(19) United States
(12) Patent Application Publication
(10) Pub. No.: US 2005/0076945 A1
(43) Pub. Date: Apr. 14, 2005

(54) Solar battery and manufacturing method thereof

(75) Inventors: Shinsuke Tachibana, Kashiba-shi (JP); Hitoshi Sannomiya, Osaka-shi (JP); Hiromasa Tanamura, Sakurai-shi (JP); Takashi Ouchida, Kitakatsuragi-gun (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka-shi (JP)

(21) Appl. No.: 10/951,723

(22) Filed: Sep. 29, 2004

(30) Foreign Application Priority Data
Oct. 10, 2003 (JP) 2003-351929(P)

(51) Int. Cl. H02N 6/00; H01L 25/00

(52) U.S. Cl. 136/244; 136/251

(57) ABSTRACT

A solar battery and a manufacturing method thereof, which includes a plurality of power generation regions having at least an insulation translucent substrate, a front surface electrode, a photoelectric conversion layer made of semiconductor films being stacked, and a back surface electrode, the front surface electrode and the back surface electrode of adjacent power generation regions being electrically connected, whereby the power generation regions are serially connected. The solar battery and the manufacturing method thereof are characterized in that the back surface electrode has a back surface metal electrode having a thickness of 100 nm-200 nm.

This nonprovisional application is based on Japanese Patent Application No. 2003-3511929 filed with the Japan Patent Office on Oct. 10, 2003, the entire contents of which are hereby incorporated by reference.

### BACKGROUND OF THE INVENTION

1. Field of the Invention

The present invention relates to a solar battery and a manufacturing method thereof.

2. Description of the Background Art

Recently, the technical development of a solar power generation system that directly generates electric energy from sunlight using a solar battery has been advancing rapidly, and its technical prospect is favorable as a power generating method for practical use. As a result, expectation for the future of the solar power generation system has been increasing, as a full-scale clean energy technique that protects the global environment of the 21 st century from the environmental pollution caused by combustion of fossil energy.

Here, materials used for solar batteries can roughly be grouped into the following four types.
(i) IV group semiconductors
(ii) compound semiconductors (III-V group, II-VI group, I-III-VI group)
(iii) organic semiconductors
(iv) compounds of TiO₂ or the like used for wet type solar power generation.

Among those, the IV group semiconductors have been introduced into practical use the most, since they can be manufactured at lower costs as compared to the rest of the materials. The IV group semiconductors can roughly be grouped into the following two groups, i.e., (1) crystalline semiconductors, and (ii) non-crystalline semiconductors (also referred to as amorphous semiconductors). Examples of materials of crystalline semiconductors used as solar batteries include monocrystalline silicon, monocrystalline germanium, polycrystalline silicon, microcrystalline silicon and the like. Additionally, an example of a non-crystal semiconductor used as a solar battery includes amorphous silicon and the like.

Here, the solar batteries manufactured using such materials of semiconductors can roughly be grouped into the following three types.
(i) pn-junction type
(ii) pin-junction type
(iii) hetero-junction type.

Among those, generally in a solar battery using a crystalline semiconductor with a long carrier diffusion distance, a pn-junction type is often employed. In a solar battery using a non-crystalline semiconductor with a short carrier diffusion distance and with a localized state, a pin-junction type is often employed as it is advantageous to move carriers through drifting by an internal electric field in an i layer (intrinsic layer).

Generally, a solar battery of pin-junction type has such a structure that, on an insulation translucent substrate of glass or the like, a transparent conductive film of SnO₂, ITO, ZnO or the like is formed, and then a p-layer, an i-layer and an n-layer of non-crystalline semiconductors are stacked thereon in this order to form a photoelectric conversion layer, on which a back surface electrode of a metal thin film or the like is stacked. Conversely, there is also a solar battery of pin-junction type having such a structure that, on a back surface electrode made of a metal thin film or the like, an-n layer, an i-layer and a p-layer of non-crystalline semiconductors are stacked in this order to form a photoelectric conversion layer, on which a transparent conductive film is stacked.

Among those method, the method wherein the layers are stacked in order of p-i-n is mainly used in these days because the translucent insulation substrate can also serve as a cover glass of a solar battery surface, and a newly developed plasma-resistant transparent conductive film of SnO₂ or the like enables stacking of the photoelectric conversion layer made of non-crystalline semiconductor thereon with a plasma CVD method.

In an attempt to further increase the voltage generated in one power generation region of a solar battery, a solar battery having a power generation region wherein two to three photoelectric conversion layers are stacked has remarkably been developed recently. Further, a solar battery of multi-band gap type has conventionally been known, wherein an upper photoelectric conversion layer (the photoelectric conversion layer on the front surface electrode side, hereinafter also referred to as “an upper cell”) and a lower photoelectric conversion layer (the photoelectric conversion layer on the back surface electrode side, hereinafter also referred to as “a lower cell”) are different in band gap so as to effectively use the energy of different wavelengths from sunlight.

Recently, development of a stacked type (so-called tandem type) solar battery wherein amorphous (non-crystalline) silicon and a crystalline silicon thin film are used as, for example, upper cell 3a and lower cell 3b, respectively, has been actively conducted aiming at commercialization, and various studies are underway.

Here, generally when driving an electronics device by a solar battery or when using a solar battery for a power supply, it is necessary to use a solar battery having a large area wherein a plurality of power generation regions are serially connected, because each of the power generation regions generates voltage of at most 1V. For example, a general solar battery is formed on an insulating substrate using a patterning process or the like, often employing such a structure that, on a translucent insulation substrate such as one glass substrate, a plurality of power generation regions having a transparent electrode, a photoelectric conversion layer and a back surface electrode are formed, and wherein these power generation regions adjacent to one another are serially connected.

Such a solar battery having the aforementioned structure wherein a plurality of power generation regions are serially connected is normally formed in the following method. First, a transparent conductive film of SnO₂, ITO, ZnO or the like is formed on an insulation translucent substrate of a glass substrate or the like, and then it is separated into rectangular pieces by laser processing. Thereafter, cleaning such as ultrasonic cleaning is performed. Next, a photoelectric conversion layer is formed thereon and the photoelectric conversion layer is separated into rectangular pieces by laser processing. A back surface electrode of ZnO/Ag or the like is formed, which is then separated into rectangular pieces by laser processing. Thereafter, ultrasonic cleaning is performed. Thereafter, to the back surface electrode, using an adhesive material of EVA (Ethylene Vinyl Acetate) or the like and using a film of PET (Polyethylene Terephthalate) film or the like, the back surface is sealed.

As described above, in the manufacture of a solar battery employing a non-crystalline silicon as the photoelectric conversion layer, the step of performing ultrasonic cleaning has been essential in order to remove the residue after the laser processing, the residue of the back surface electrode layer and the like after the back surface electrode is separated by laser processing. Specifically, after laser processing, a burr 8a of a back surface electrode 4 such as shown in FIG. 4 as an example tends to be generated. The existence of such burr 8a does not pose a problem so long as it does not contact to a transparent conductive film 2 as shown in FIG. 4. On the other hand, as shown in FIG. 5, when burr 8a is greater than the value obtained by adding thickness W1 of an upper cell 3a and thickness W2 of a lower cell 3b (=W1+W2), it is more likely to contact to transparent conductive film 2. Specifically, transparent conductive film 2 contacting to back surface electrode 4 via burr 8a results in leak. Further, when a burr 8b of a metal electrode of back surface electrode 4 that is greater than width W3 of a back surface electrode separation line 7 is present as shown in FIG. 6, burr 8b may cross over separation line 7 as shown in FIG. 7 thereby resulting in leak between the cells. These leaks invite deterioration of the properties of the solar battery. Generally, back surface electrode 4 side is sealed for preventing oxidation or the like of the back surface metal electrode of back surface electrode 4. At the stage of this sealing, burrs 8a and 8b of back surface electrode 4 are likely to be in the states shown in FIGS. 5 and 6. Conventionally, a cleaning method has always been necessary after laser processing in order to prevent defects due to these burrs. Normally, ultrasonic cleaning is performed with the frequencies of 20-100 kHz, and also a drying step that follows has been required.

On the other hand, in case of the tandem solar battery wherein the photoelectric conversion layer is formed using non-crystalline/crystalline silicon, while thickness W1 of upper cell 3a is about 0.15 μm-0.5 μm, thickness W2 of lower cell 3b requires a substantially great thickness of about 2 μm-3 μm, due to the difference in light absorption coefficient. Accordingly, if a solar battery is produced following the similar steps as a non-crystalline silicon, a film peels off in the cleaning step after laser processing of back surface electrode 4, which results in deterioration of properties and/or problems in the appearance.

In order to prevent such peeling, various method have been contemplated. For example, in Japanese Patent Laying-Open No. 2001-308362, a method is proposed wherein peeling is prevented by setting the thickness of a crystalline silicon thin film in a range of 1 μm-1.5 μm to reduce residual stress, and thereafter performing a cleaning step. In Japanese Patent Laying-Open No. 2001-237445, as the cleaning following the laser processing, bubble jet ultrasonic cleaning wherein gases are mixed and high-pressure water is used, and ultrasonic cleaning of megasonic have been proposed. In Japanese Patent Laying-Open No. 11-330513, a cleaning method by an adhesive tape has bee proposed for removing the residues after the laser processing.

In any of the methods disclosed in Japanese Patent Laying-Open No. 2001-308362, Japanese Patent Laying-Open No. 2001-237445 and Japanese Patent Laying-Open No. 11-330513, a cleaning method of a certain kind is employed for removing the residues or the like after performing laser processing. As used herein, cleaning includes any method for removing residues after performing laser processing of the back surface electrode, and it includes a method such as injection gas, in addition to ultrasonic cleaning. It is further noted that, according to the method disclosed in Japanese Patent Laying-Open No. 2001-308362, the energy conversion efficiency of the solar battery may be sacrificed for reducing the thickness.

FIG. 8 is a plan view of a light-transmitting type solar battery 100 (hereinafter referred to as a “see-through type solar battery”), wherein part of a film is removed by laser processing and an opening portion 9 is provided in a power generation region. This see-through type solar battery 100 can be classified into a type of solar battery of which cross-sectional structure along IX-IX of FIG. 8 shows a structure shown in FIG. 9 or a structure shown in FIG. 10. The see-through type solar battery having the structure shown in FIG. 9 has such a structure that, in a power generation region, photoelectric conversion layer 3 and back surface electrode 4 are partially removed by laser processing, opening portion 9 is provided, and a face of transparent conductive film 2 is exposed. The see-through type solar battery having the structure shown in FIG. 10 has such a structure that, in a power generation region, transparent conductive film 2, photoelectric conversion layer 3 and back surface electrode 4 are partially removed by laser processing, opening portion 9 is provided, and a face of insulation translucent substrate 1 is exposed.

In any of the see-through solar batteries shown in FIGS. 9 and 10, laser processing is performed so that about 0.5 mm-5 mm of pitch W5 of opening portion 9 is attained to obtain a desired rate of opening portions. Therefore, the number of laser processing regions (i.e., the processing numbers) is great, and peeling becomes more likely to be invited by the step of ultrasonic cleaning.

Additionally, in order to transmit light, back surface electrode 4 must be sealed with a transparent object of glass or the like. It is disadvantageous in appearance if peeling as described above occurs. Accordingly, it is particularly important in a see-through type solar battery to produce the solar battery preventing burrs after laser processing and without performing cleaning.

Further, in the see-through type solar battery having the structure shown in FIG. 10, since laser processing is performed including transparent conductive film 2 that is conductive, cleaning such as ultrasonic cleaning must be performed for removing the residues after laser processing is performed.

### SUMMARY OF THE INVENTION

The present invention is made to solve the problems described above, and its object is to provide a manufacturing method of a solar battery that enables excellent yield and reduced manufacturing costs and that does not require cleaning after a back surface electrode is subjected to laser processing, and to provide a solar battery (particularly, a see-through type solar battery) manufactured by the method.

In an attempt to solve the problems described above, the inventors of the present invention found a structure and a manufacturing method thereof that enables to suppress generation of burrs after laser processing and that enables production of a solar battery without cleaning, by determining the substantial factor that causes generation of burrs after laser processing, and by noting the thickness of the metal electrode of the back surface electrode.

Specifically, the solar battery of the present invention is a solar battery including a plurality of power generation regions having at least an insulation translucent substrate, a front surface electrode, a photoelectric conversion layer made of semiconductor films being stacked, and a back surface electrode. The front surface electrode and the back surface electrode of adjacent power generation regions are electrically connected, whereby the power generation regions are serially connected. The solar battery is characterized in that a back surface metal electrode has a thickness of 100 nm-200 nm. Thus, generation of burrs after laser processing of a back surface electrode is suppressed, and a solar battery can be provided that can be manufactured without cleaning after laser processing and still with its properties not damaged.

Preferably, in order from the insulation translucent substrate side, the photoelectric conversion layer of the present invention is formed by stacking an upper photoelectric conversion layer in which each of p-type, i-type and n-type semiconductor films formed of amorphous silicon is stacked, and a lower photoelectric conversion layer in which each of p-type, i-type and n-type semiconductor films formed of microcrystalline silicon is stacked. Thus, an effect of preventing films from peeling off can be attained.

Preferably, in the solar battery of the present invention, a plurality of opening portions processed in a manner of slits perpendicular to an integration direction to transmit light to their back surface side are formed, and the photoelectric conversion layer and the back surface electrode are separated at the opening portion. Thus, an effect of preventing films from peeling off can fully be attained. It is noted that, desirably, a transparent conductive film is unseparated at the opening portion.

The present invention also provides a see-through type solar battery module including power generation regions having at least an insulation translucent substrate, a front surface electrode, a photoelectric conversion layer made of semiconductor films being stacked, and a back surface electrode. The front surface electrode and the back surface electrode of adjacent power generation regions are electrically connected, whereby the plurality of the power generation regions are serially connected. The see-through type solar battery module is characterized in that said back surface electrode has a back surface metal electrode having a thickness of 100 nm-200 nm, a plurality of opening portions processed in a manner of slits perpendicular to an integration direction to transmit light to their back surface side are formed, and a back surface electrode side is sealed with an adhesive layer and a transparent sealing material. Preferably, such a see-through type solar battery module also has characteristics similarly to the solar battery described above.

The present invention also provides a method for manufacturing a solar battery. The method according to the present invention is a method for manufacturing a solar battery including power generation regions having at least an insulation translucent substrate, a front surface electrode, a photoelectric conversion layer made of semiconductor films being stacked, and a back surface electrode. The front surface electrode and the back surface electrode of adjacent power generation regions are electrically connected, whereby the plurality of the power generation regions are serially connected. The method includes at least the steps of forming a back surface electrode having a back surface metal electrode having a thickness of 100 nm-200 nm, and separating the back surface metal electrode by laser processing, and characterized in that a cleaning step is not performed after separating the back surface metal electrode. According to the manufacturing method of the present invention, a solar battery can be manufactured drastically efficiently and at low costs than a conventional method. Preferably, in the manufacturing method of the present invention, laser processing of the back surface metal electrode is performed by irradiation of second-harmonic generation of Nd:YAG or Nd:YVO₄ laser from a glass surface.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing a structure of a solar battery 100 according to the present invention.

FIG. 2 is a graph showing the relationship among thickness of a back surface metal electrode, output after the back surface electrode being scribed, and changes in output before and after sealing the back surface.

FIG. 3 is a graph showing the relationship between thickness of silver and output after sealing the back surface (made into a module).

FIG. 4 is a schematic illustration showing one example of a burr that is a defect generated from processing of an integration portion.

FIG. 5 is a schematic illustration showing one example of a burr, which is a defect generated from processing of an integration portion, inviting leak between cells.

FIG. 6 is a schematic illustration showing one example of a burr that is a defect generated from processing of an integration portion.

FIG. 7 is a schematic illustration showing one example of a burr, which is a defect generated from processing of an integration portion, inviting leak between cells.

FIG. 8 is a plan view of a see-through type solar battery.

FIG. 9 is a schematic illustration showing an exemplary structure of a cross section along IX-IX of FIG. 8 that is a plan view of a see-thorough type solar battery.

FIG. 10 is a schematic illustration showing another exemplary structure of a cross section along IX-IX of FIG. 8 that is a plan view of a see-thorough type solar battery.

### DESCRIPTION OF THE PREFERRED EMBODIMENTS

In the following, the present invention will be described in detail.

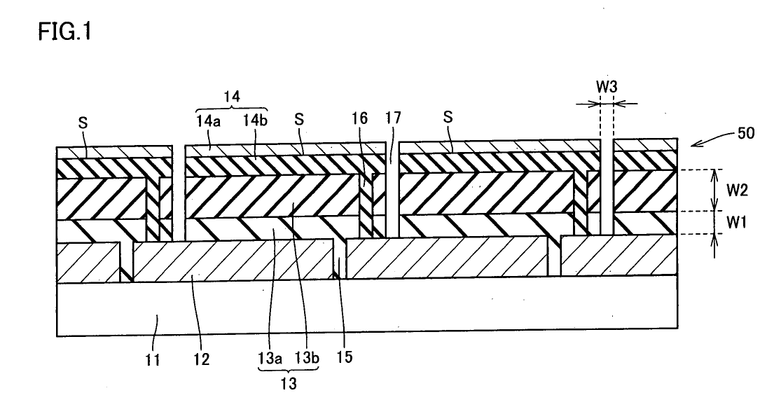

FIG. 1 is a cross-sectional view schematically showing a solar battery 50 according to the present invention. Solar battery 50 of the present invention includes a plurality of power generation regions S having at least an insulation translucent substrate 11, a front surface electrode 12, a photoelectric conversion layer 13 made of semiconductor films being stacked, and a back surface electrode 14. The front surface electrode and the back surface electrode of adjacent power generation regions are electrically connected, whereby the power generation regions are serially connected. The solar battery is characterized in that the back surface electrode 14 has a back surface metal electrode having a thickness of 100 nm-200 nm. Here, the thickness of the back surface metal electrode refers to a length along a thickness direction of the insulation translucent substrate in a flat-shaped portion of the back surface metal electrode (i.e., not the portion of a filled open-groove, which will be described later).

In a conventional solar battery, it has been normal for the back surface metal electrode to have a thickness of about 300 nm-500 nm, in a design with margin for preventing oxidation of the side exposed to the air. On the other hand, in the present invention, a thickness of 100 nm-200 nm (particularly preferably, 150 nm) is achieved by applying a sheet for preventing oxidation or the like after laser processing of the back surface electrode. Thus, as generation of burrs at the time of dividing the back surface electrode by laser processing, which will be described later, is prevented by an improvement of adhesiveness of the back surface metal electrode, a solar battery can be manufactured without performing a cleaning step of ultrasonic cleaning or the like, which has been required to be performed after laser processing conventionally, and without deterioration of the properties. Specifically, when the thickness of the back surface metal electrode is less than 100 nm, the energy conversion efficiency is disadvantageously reduced due to reduction in reflection rate and the like. When the thickness of the back surface metal electrode is more than 200 nm, burrs may be generated after laser processing and deterioration of the properties is more likely to occur after sealing the back surface electrode side. Therefore, in either case, the effect of the present invention as described above cannot be attained.

The solar battery of the present invention is also advantageous in that the costs of materials in manufacture can be reduced, as the thickness of the back surface metal electrode in the back surface electrode is set to be to 100 nm-200 nm so as to minimize the thickness of the metal of the back surface electrode.

In the following, each constituent of the solar battery of the present invention will be described in detail.

Insulation translucent substrate 11 used for solar battery 50 of the present invention is not limited specifically so long as it has insulation and translucency, and a substrate generally used for a solar battery can be used. Specific example of insulation translucent substrate 11 used for the present invention includes a substrate using glass, quartz, plastic with transparency or the like as its material. It should be noted that, it is not necessary for all portions of insulation translucent substrate 11 used for the present invention to have insulation, and a substrate can be used if at least its electrode formation side is insulated. Specifically, even a conductive substrate can be employed as the insulation translucent substrate used for the present invention, by covering the electrode formation side with an insulating material.

Front surface electrode 12 used for solar battery 50 of the present invention is formed on insulation translucent substrate 11. Here, front surface electrode 12 used for the present invention is not limited specifically so long as it has conductivity and translucency, and front surface electrode 12 generally used for a solar battery can be used. As front surface electrode 12 used for the present invention, a film-like electrode (in the present specification, it is referred to as a “transparent conductive film”) made of a material having translucency and conductivity is preferable. It should be noted that, it is not necessary for all portions of front surface electrode 12 used for the present invention to have translucency, and it can be used if at least one portion thereof has translucency and has transparency that enables transmission of light in a quantity required for solar power generation. Specifically, with an electrode using a material of metal or the like that does not have translucency, if it is has a lattice-like structure, for example, it has translucency. Hence, it can be employed as the front surface electrode used for the present invention.

Specific example of front surface electrode 12 used for the present invention includes a transparent conductive film using tin oxide, zinc oxide, ITO or the like as a material. Here, tin oxide includes not only SnO₂ but also tin oxide of various composition expressed by SnₘOₙ (where m and n are positive integers). Also, zinc oxide includes not only ZnO but also zinc oxide of various composition expressed by Zn_{m′}O_{n′} (where m′ and n′ are positive integers). ITO is an abbreviation of Indium Tin Oxide. Here, while ITO and SnO₂ are not largely different in translucency, it is considered that generally ITO is lower in specific resistance and SnO₂ is greater in chemical stability. Additionally, ZnO has an advantage that it is lower in material costs than ITO. Further, while SnO₂ may pose a problem due to reduction of the surface by plasma when forming a-Si film, ZnO is highly plasma-resistant. Additionally, ZnO has also an advantage that it has high transmittance of light of long wavelength.

When front surface electrode 12 used for the present invention is made of a transparent conductive film made of a material containing ZnO, impurities of Al, Ga or the like may be doped so as to reduce resistance of the transparent conductive film. Among those, it is preferable to dope Ga that has a property of greatly reducing the resistance.

Photoelectric conversion layer 13 used for the solar battery of the present invention is not limited specifically so long as it has a structure made of semiconductor films being stacked and it has photoelectric convertibility, and a photoelectric conversion layer generally used for a solar battery can be used. Here, as for a material of each of the semiconductor films forming the photoelectric conversion layer used for the present invention, material generally used for a photoelectric conversion layer of a solar battery can be used, so long as it is a semiconductor. Specific example thereof includes Si, Ge, SiGe, SiC, SiN, GaAs, SiSn or the like may be used. Among those, preferably Si, SiGe, SiC or the like, which are silicon-based semiconductors, may be used.

A semiconductor that is a material of each of semiconductor films forming photoelectric conversion layer 13 used for the present invention may be a crystalline semiconductor of a microcrystalline or polycrystalline type, or it may be a non-crystal semiconductor such as an amorphous type. Here, as non-crystalline and polycrystalline type semiconductors, it is preferable to use a hydrogenated semiconductor wherein a dangling bond causing a localized state is terminated with hydrogen.

Preferably, the photoelectric conversion layer used for the present invention has a three-layer structure in which semiconductors of p-type, i-type and n-type are stacked. Semiconductors of p-type and n-type can be formed by doping prescribed impurities, as widely practiced in the field of the art conventionally. Preferably, the three-layer structure is a p-i-n type wherein a p-layer, an i-layer, and an n-layer are stacked from a light entering surface side in this order.

In the present invention, a structure wherein a plurality of photoelectric conversion layers are stacked is also possible. When a plurality of photoelectric conversion layers are stacked, materials and structures of semiconductor films forming the photoelectric conversion layers may be the same or may be different.

In the viewpoint of preventing semiconductor films from peeling off, preferably photoelectric conversion layer 13 in the present invention is formed by, in order from the insulation translucent substrate side, stacking an upper photoelectric conversion layer in which each of p-type, i-type, and n-type semiconductor films formed of amorphous silicon is stacked, and a lower photoelectric conversion layer in which each of p-type, i-type, and n-type semiconductor films formed of microcrystalline silicon is stacked. Specifically, it is preferable to be implemented as a so-called tandem structure, wherein, from the insulation translucent substrate side, via a front surface electrode, an upper photoelectric conversion layer (upper cell) 13a formed of a three-layer structure of p-i-n type of a hydrogenated amorphous silicon-based semiconductor (a-Si:H), and a lower photoelectric conversion layer (lower cell) 13b formed of a three-layer structure of p-i-n type of a hydrogenated microcrystalline silicon-based semiconductor (μc-Si:H) are stacked.

Though the thickness of photoelectric conversion layer 13 in the present invention is not specifically limited, it is preferable that the total thickness thereof is in a range of 1.8 μm-3.5 μm, more preferable 2.0 μm-3.0 μm, in order to attain a certain degree of conversion efficiency, though the thickness depends on a film deposition condition of the photoelectric conversion layer and it is related to the stress of a film. When forming a photoelectric conversion layer having an upper cell and a lower cell as described above, the thickness of upper cell 13a is preferably in a range of 0.2 μm-0.5 μm, more preferably 0.25 μm-0.35 μm, in a viewpoint of stabilizing efficiency, though it depends on the shape of a front surface electrode being used, the balance of current between the lower cell, and design of the rate of light degradation. The thickness of lower cell 13b is preferably in a range of 1.5 μm-3.0 μm, more preferably 1.7 μm-2.5 μm, in order to attain a certain degree of conversion efficiency, though the thickness depends on a film deposition condition of the photoelectric conversion layer and it is related to the stress of a film. As used herein, each “thickness” of the photoelectric conversion layer, the upper cell and the lower cell refers to a length along a thickness direction of an insulation translucent substrate in a flat-shaped portion in each of the photoelectric conversion layer, the upper cell and the lower cell (i.e., not the portion of a filled open-groove, which will be described later).

Back surface electrode 14 used for the present invention is formed on the opposite side (in the present specification also referred to as a “back surface side”) to a light entering surface side of photoelectric conversion layer 13. Back surface electrode 14 used for the present invention is not specifically limited, so long as it has a back surface metal electrode having, in addition to conductivity, light scattering property or light reflectivity and having a thickness of 100 nm-200 nm. Specific example of the back surface metal electrode used for the present invention includes a metal film wherein. Ag, Al, Cr or the like that are excellent in light reflectivity, and among those, a metal film formed of Ag is preferable since it has particularly high reflection rate.

Though back surface electrode 14 used for the present invention may be formed only by the back surface metal electrode, preferably a back surface transparent electrode is stacked on the back surface metal electrode in order to facilitate light scattering to attain high efficiency of power generation. Specific example of the back surface transparent electrode used for the present invention includes a transparent conductive film using tin oxide, zinc oxide, ITO or the like as a material. Here, tin oxide includes not only SnO₂ but also tin oxide of various composition expressed by SnₘOₙ (where m and n are positive integers). Also, zinc oxide includes not only ZnO but also zinc oxide of various composition expressed by Zn_{m′}O_{n′} (where m and n are positive integers). ITO is an abbreviation of Indium Tin Oxide. Here, while ITO and SnO₂ are not largely different in translucency, it is considered that generally ITO is lower in specific resistance and SnO₂ is greater in chemical stability. Additionally, ZnO has an advantage that it is lower in material costs than ITO.

When back surface electrode 14 in the present invention has a back surface transparent electrode in addition to the back surface metal electrode, preferably the thickness of the back surface transparent electrode is 0.03 μm-0.2 μm. Here, also for the “thickness” of the back surface transparent electrode, similarly to the “thickness” of the back surface metal electrode, it refers to a length along a thickness direction of an insulation translucent substrate in each flat-shaped portion in the back surface transparent electrode (i.e., not the portion of a filled open-groove, which will be described later).

Solar battery 50 of the present invention basically has such a structure, that it includes power generation regions S having insulation translucent substrate 11, front surface electrode 12, a photoelectric conversion layer 13 made of semiconductor films being stacked, and a back surface electrode 14, in which front surface electrode 12 and the back surface electrode 14 of adjacent power generation regions S are electrically connected, whereby a plurality of power generation regions S are serially connected. Here, in order to attain a structure where such a plurality of power generation regions S are serially connected (in the present specification also referred to as a “serial stack structure”) in solar battery 50 of the present invention, between adjacent power generation regions S, respective surface electrodes 11, photoelectric conversion layers 13, back surface electrodes 14 must be completely separated. Further, in order for solar battery 50 of the present invention to attain an integrated structure, between adjacent power generation regions S, front surface electrode 12 and back surface electrode 14 must be serially connected. Accordingly, the solar battery of the present invention must include an open groove 15 for separating the front surface electrode (in the present specification also referred to as a “front surface electrode separation line 15”), an open groove 16 for separating the photoelectric conversion layer (in the present specification also referred to as a “photoelectric conversion layer separation line 16”), and an open groove 17 for separating the back surface electrode (in the present specification also referred to as a “back surface electrode separation line 17”). Here, the inside of each open grooves 15, 16 and 17 is not limited to be a gap, and a semiconductor, an electrode or the like may be present like a film or so that the inside is filled. In the present specification, such a situation is also referred to as an open groove. Additionally, in solar battery 50 of the present invention, in order to attain the serial stack structure, a member (a contact line) for electrically connecting the front surface electrode and back surface electrode is also required.

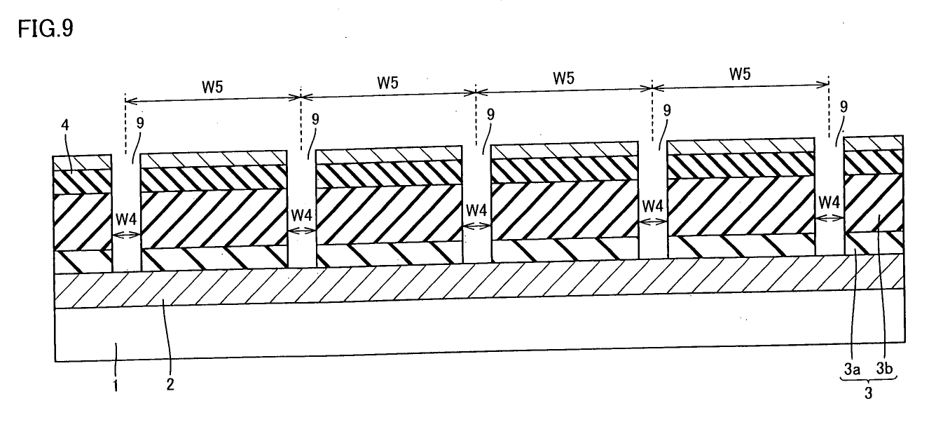

The solar battery of the present invention is implemented as a light-transmitting type solar battery (a see-through type solar battery) wherein a plurality of opening portions processed in a manner of slits perpendicular to an integration direction and transmit light to their back surface side are formed, and preferably the photoelectric conversion layer and said back surface are separated by the opening portion. Here, the integration direction refers to, in a solar battery in which on an insulation translucent substrate, a surface electrode, a photoelectric conversion layer and a back surface electrode are stacked serially and integrated, the direction to which the stacked surface electrode, photoelectric conversion layer and back surface electrode extend (for example, the direction perpendicular to the paper surface in the example of FIG. 1). As will be described later referring to Example 4 and Comparative Example 4, from a viewpoint of preventing deterioration of properties by see-through processing, it is necessary that the transparent conductive film is not separated by the opening portion (i.e., has a cross-sectional shape shown in FIG. 9).

In the see-through type solar battery of the present invention, the total area of its opening portions is preferably 4%-30% relative to an effective power generation area, and more preferably 7%-20%. When the proportion of the total area of the opening portions is less than 4%, an opening portion pitch increases and the design tends to be impaired. On the other hand, when the proportion of the total area of the opening portions is more than 30%, the solar battery output unduly decreases, longer processing time is required, while the design is not improved.

The present invention also provides a see-through type solar battery module, including a plurality of power generation regions having at least an insulation translucent substrate, a surface electrode, a photoelectric conversion layer made of semiconductor films being stacked, and a back surface electrode. The surface electrode and the back surface electrode of adjacent power generation regions are electrically connected, whereby the power generation regions are serially connected. The back surface electrode has a back surface metal electrode having a thickness of 100 nm-200 nm. A plurality of opening portions processed in a manner of slits perpendicular to an integration direction and transmit light to their back surface side are formed. A back surface electrode side is sealed by an adhesive layer and a transparent sealing material. Accordingly, in the present invention, it is possible to obtain a solar battery without performing a cleaning step after laser processing of the back surface electrode, and a see-through type solar battery module can be obtained at drastically higher efficiency and lower costs than by a conventional manner.

In the see-through type solar battery module of the present invention, a material of an adhesive layer used for sealing the back surface electrode side is not specifically limited, and a conventionally known material, for example EVA or the like, can be used. A transparent sealing material used for sealing the back surface electrode side is not specifically limited, and a conventionally known material, for example PET (Polyethylene Terephthalate) film, PVB (Polyvinyl Butyral) film or the like may be used.

A method for manufacturing a solar battery of the present invention is a method for manufacturing a solar battery including a plurality of power generation regions having at least an insulation translucent substrate, a surface electrode, a photoelectric conversion layer made of semiconductor films being stacked, and a back surface electrode. The surface electrode and the back surface electrode of adjacent power generation regions are electrically connected, whereby the plurality of power generation regions are serially connected. The method includes at least a step of forming a back surface electrode having a back surface metal electrode having a thickness of 100 nm-200 nm (a back surface electrode forming step) and a step of separating the back surface metal electrode by laser processing (a back surface electrode patterning step), and characterized in that a cleaning step is not performed after separating the back surface metal electrode. In the manufacturing method of the present invention, the steps except for the back surface electrode forming step and the back surface electrode patterning step should be employed from a conventional method for manufacturing a solar battery as appropriate, except that the cleaning step is not performed after separating the back surface metal electrode, and they are not specifically limited. For example, the solar battery of the present invention should be manufactured following the steps similarly to a conventional manner, i.e., (1) front surface electrode forming step, (2) front surface electrode patterning step, (3) photoelectric conversion layer forming step, and (4) photoelectric conversion layer patterning step. Then, the steps that characterize the present invention, i.e., (5) the back surface electrode forming step and (6) the back surface electrode patterning step should be performed, without performing a cleaning step.

In the following, one specific example of the manufacturing method of the present invention will be described step by step.

(1) The Front Surface Electrode Forming Step

First, on an insulation translucent substrate, a front surface electrode is formed. The front surface electrode forming step is different depending on whether the front surface electrode is a metal electrode or a transparent conductive film.

When the front surface electrode is a metal electrode, as a front surface electrode forming step, a physical producing method can be used. The physical producing method may include, and not limited to, a vacuum deposition method, an ion plating method, a sputtering method, a magnetron sputtering method and the like, for example. Among those manufacturing methods, the sputtering method is preferable to be employed in the viewpoint of quality and the like.

When the front surface electrode used for the present invention is a transparent conductive film, as the front surface electrode forming step, a chemical producing method or a physical producing method can be used. The chemical producing method may include, and not limited to, a spraying method, a CVD method, a plasma CVD method or the like, for example. Generally, the chemical producing method is a method for forming an oxide film on a substrate by pyrolysis and oxidation reaction of chloride, organic metal compound or the like, and its advantage is low process costs. The physical producing method may include a vacuum deposition method, an ion plating method, a sputtering method, a magnetron sputtering method and the like, for example. Generally, a physical producing method provides lower temperature of the substrate than a chemical producing method and capable of forming a film of an excellent quality, while the film deposition speed tends to be slow and the apparatus tends to be costly.

(2) The Front Surface Electrode Patterning Step

Next, by patterning the front surface electrode formed by step (1), a front surface electrode separation line is formed. The method of patterning is not specifically limited, and a method generally used for patterning a metal electrode or a transparent conductive film may suitably be used so long as it is a method that enables precise patterning. For example, patterning of the front surface electrode can be performed by etching using a resin mask, a metal mask or the like. However, such a method is involved with problems. For example, large number of processes are required for forming a layer-stacked structure, the size of a substrate that can be processed is limited, an effective area of a power generation region within a substrate of a solar battery tends to be small, pin holes are likely to be generated in the photoelectric conversion layer due to the wet process, and patterning is difficult with a curved substrate.

Accordingly, in the front surface electrode forming step, it is preferable to perform patterning utilizing heating by irradiation of laser (in the present specification also referred to as “laser patterning”). By performing such laser patterning, the following advantages can be obtained. Specifically, the number of steps required for forming a layer-stacked structure can be reduced, a solar battery can be manufactured on a substrate of a large area, a solar battery can be manufactured on a substrate of any shape such as a curved shape, an effective area of a power generation region within a substrate of a solar battery can be increased, and becoming suitable for continuous production and automated production. Here, a laser used for laser patterning is not specifically limited, and a laser generally used in a method for manufacturing a solar battery can be used. Preferably, the distance between a laser output port and an irradiated surface, the diameter of the laser on the irradiated surface and laser irradiation time are selected as appropriate in accordance with the shape of patterning and the like. Preferably, after the front surface electrode patterning step and before performing a photoelectric conversion layer forming step, which will be described later, the substrate and the front surface electrode are cleaned by pure water.

(3) The Photoelectric Conversion Layer Forming Step

Next, on the surface electrode to which patterning is provided by step (2), a photoelectric conversion layer is formed. A photoelectric conversion layer can be formed by a conventionally known method as appropriate, and the formation method is not specifically limited. For example, photoelectric conversion layer can be formed by a chemical producing method or a physical producing method.

The chemical producing method in the photoelectric conversion layer forming step may include the spraying method, the CVD method, the plasma CVD method or the like, for example. Generally, the chemical producing method of a semiconductor is a method for forming a semiconductor film on a substrate by pyrolysis and plasma reaction of a raw material gas such as silane gas, and its advantage is low process costs.

The physical producing method in the photoelectric conversion layer forming step may include the vacuum deposition method, the ion plating method, the sputtering method, the magnetron sputtering method and the like, for example. Generally, a physical producing method provides lower temperature of the substrate than a chemical producing method and capable of forming a film of an excellent quality, while the film deposition speed tends to be slow and the apparatus tends to be costly. Among those manufacturing methods, the plasma CVD method is preferable to be employed in the viewpoint of quality and the like.

From the method described above, a photoelectric conversion layer having a three-layer structure in which semiconductor films of p-type, i-type, and n-type are stacked can preferably be obtained. When a plurality of photoelectric conversion layers are to be stacked (for example, when an upper cell formed of a three-layer structure of p-i-n type of a hydrogenated amorphous silicon-based semiconductor (a-Si:H), and a lower cell formed of a three-layer structure of p-i-n type of a hydrogenated microcrystalline silicon-based semiconductor (>c-Si:H) are to be stacked), the chemical producing method and/or physical producing method may be repeatedly performed.

(4) The Photoelectric Conversion Layer Patterning Step

Next, by patterning the photoelectric conversion layer formed by step (3), a photoelectric conversion layer separation line is formed. The method of patterning is not specifically limited, and method generally used for patterning a photoelectric conversion layer or a transparent conductive film may suitably be used so long as it is a method that enables precise patterning. For example, patterning can be performed by etching using a resin mask, a metal mask or the like. However, such a method is involved with problems. For example, large number of processes are required for forming a layer-stacked structure, the size of a substrate that can be processed is limited, an effective area of a power generation region within a substrate of a solar battery tends to be small, pin holes are likely to be generated in the photoelectric conversion layer due to the wet process, and patterning is difficult with a curved substrate.

Accordingly, in the photoelectric conversion layer patterning step, it is preferable to perform patterning utilizing heating by irradiation of laser (laser patterning). By performing such laser patterning, the following advantages can be obtained. Specifically, the number of steps required for forming a layer-stacked structure can be reduced, a solar battery can be manufactured on a substrate of a large area, a solar battery can be manufactured on a substrate of any shape such as a curved shape, an effective area of a power generation region within a substrate of a solar battery can be increased, and becoming suitable for continuous production and automated production.

Here, in the photoelectric conversion layer patterning step, as a laser used for laser patterning, when the front surface electrode is made of a transparent conductive film, it is preferable to use a visible light range laser that is superior in passing the transparent conductive film, in order not to damage the transparent conductive film. Therefore, it is preferable to use, for example, a YAG SHG laser.

In the photoelectric conversion layer patterning step, it is preferable to form an open groove for forming a contact line.

(5) The Back Surface Electrode Forming Step

Next, the back surface electrode is formed. When forming this back surface electrode, it is preferable to fill the open groove for forming a contact line with a conductive material to form the contact line. The conductive material is not specifically limited so long as it has conductivity, and a conductive material generally used for a solar battery can be used. From the viewpoint of simplifying the manufacturing steps, when the back surface electrode is made of a back surface metal electrode and a back surface transparent electrode, it is preferable to use a conductive material made of the same material as the back surface transparent electrode. It is desired that, by forming a contact line, the open groove of the contact line is completely filled with the conductive material, and the front surface electrode and the back surface electrode are fully electrically connected.

Though the formation method of the back surface metal electrode in the back surface electrode is not specifically limited, it is preferable to form by a physical producing method. The physical producing method may include the vacuum deposition method, the ion plating method, the sputtering method, the magnetron sputtering method and the like, for example. Among those manufacturing methods, the magnetron sputtering method is preferable to be employed in the viewpoint of quality and the like. In the manufacturing method of the present invention, it is important to form the back surface metal electrode to have a thickness of 100 nm-200 nm in this back surface electrode forming step. The back surface metal electrode having such a thickness can suitably be formed by adjusting conditions or the like as appropriate in each of the methods described above.

When forming a back surface transparent electrode in addition to the back surface metal electrode, the back surface transparent electrode can be formed by a chemical producing method or a physical producing method. The chemical producing method may include the spraying method, the CVD method, the plasma CVD method or the like, for example. Generally, the chemical producing method is a method for forming an oxide film on a substrate by pyrolysis and oxidation reaction of chloride, organic metal compound or the like, and its advantage is low process costs. The physical producing method may include the vacuum deposition method, the ion plating method, the sputtering method, the magnetron sputtering method and the like, for example. Generally, a physical producing method provides lower temperature of the substrate than a chemical producing method and capable of forming a film of an excellent quality, while the film deposition speed tends to be slow and the apparatus tends to be costly. Among those manufacturing methods, it is preferable to use the sputtering method from the viewpoint of quality and the like. In such a case, it is preferable to form the back surface transparent electrode first, which also serves as a contact line, and thereafter to form the back surface metal electrode.

(6) The Back Surface Electrode Patterning Step

Next, by patterning the back surface electrode formed by step (5), a back surface electrode separation line is formed. The method of patterning in this step is not specifically limited, and a method generally used for patterning a metal electrode or a transparent conductive film may suitably be used so long as it is a method that enables precise patterning. For example, patterning can be performed by etching using a resin mask, a metal mask or the like. However, such a method is involved with problems. For example, large number of processes are required for forming a layer-stacked structure, the size of a substrate that can be processed is limited, an effective area of a power generation region within a substrate of a solar battery tends to be small, pin holes are likely to be generated in the photoelectric conversion layer due to the wet process, and patterning is difficult with a curved substrate.

Accordingly, in the back surface electrode patterning step of the present invention, it is preferable to perform patterning utilizing heating by irradiation of laser (in the present specification also referred to as “laser patterning”). By performing such laser patterning, the following advantages can be obtained. Specifically, the number of steps required for forming a layer-stacked structure can be reduced, a solar battery can be manufactured on a substrate of a large area, a solar battery can be manufactured on a substrate of any shape such as a curved shape, an effective area of a power generation region within a substrate of a solar battery can be increased, and becoming suitable for continuous production and automated production.

As a laser used for laser patterning in the back surface electrode patterning step of the present invention, it is preferable to use Nd:YAG or Nd:YVO₄ laser. Though either laser of second-harmonic generation or third-harmonic generation may be used, the second-harmonic generation is preferable, judging by the degree of burr generation after processing. Preferably, the distance between a laser output port and an irradiated surface, laser irradiation time and the like are selected as appropriate in accordance with the shape of patterning and the like.

The manufacturing method of the present invention is characterized by not performing a cleaning step after the back surface electrode patterning step. As used herein, a “cleaning step” includes, in addition to an ultrasonic cleaning, cleaning by pure water, cleaning by an adhesive tape, cleaning using the air and the like. According to the manufacturing method of the present invention, while such a cleaning step is not performed, burr generation is prevented and a solar battery obtained thereby does not show deterioration in its property.

When manufacturing a see-through type solar battery, an opening portion is formed by laser irradiation to the back surface electrode, to which the patterning process has been provided, with the second-harmonic generation of Nd:YAG from a glass surface. Preferably, the laser processing conditions that do not damage transparent conductive film 12 are selected.

Further, by sealing the back surface electrode side with an adhesive layer and a transparent sealing material, a see-through type solar battery module can be formed. The formation of the seal of the back electrode side may be performed according to a conventionally known method, and it is not specifically limited.

### EXAMPLE 1

Using a glass substrate having a thickness of about 4.0 mm as insulation translucent substrate 11, on the glass substrate (substrate size 560 mm×925 mm), SnO₂ (tin oxide) was deposited by thermal CVD method as transparent conductive film 12.

Next, using fundamental harmonic of YAG laser, patterning of transparent conductive film 12 was performed. By setting the light to enter from the glass surface, transparent conductive film 12 was separated into rectangular pieces and surface electrode separation line 15 was formed.

Thereafter, the substrate was subjected to an ultrasonic cleaning by pure water, and thereafter upper cell 13a was formed. Upper cell 13a was formed of a-Si:Hp layer, a-Si:Hi layer, and a-Si:Hn layer, and the total thickness W1 was set to be about 0.25 μm. It should be noted that p-layer and n-layer may be μc-Si:H.

Next, lower cell 13b was formed. Lower cell 13b was formed of μc-Si:Hp layer, μc-Si:Hi layer, and μc-Si:Hn layer, and the total thickness W2 was about 2.4 μm.

Next, using the second-harmonic generation of YAG laser, patterning using a laser was performed to lower cell 13b. By setting the light to enter from the glass surface, lower cell 13b was separated into rectangular pieces, and contact line 16 for electrically connecting transparent conductive film 12 and back surface electrode 14 was formed.

Next, by the magnetron sputtering method, ZnO (zinc oxide)/Ag of back surface electrode 14 was formed. Here, ZnO (the back surface transparent electrode) was set to have a thickness of 100 nm. The thickness of silver (the back surface metal electrode) was set to be 150 nm.

Next, using a laser, patterning was performed to back surface electrode 14. By setting the light to enter from the glass surface, back surface electrode 14 was separated into rectangular pieces, and back surface electrode separation line 17 was formed. Here, in order to avoid damage to transparent conductive film 12 by the laser, the second-harmonic generation of Nd:YAG laser that is superior in passing transparent conductive film 12 was used as the laser. Width W1 of back surface electrode separation line 17 was 85 μm. Separation line 17 was observed by a microscope, and almost no burr was found.

Thereafter, a terminal was connected to the electrode portion, the first measurement was performed with solar simulator AM1.5(10 mW/cm²). Subsequently, without performing a cleaning step, back surface electrode 14 side was sealed using an adhesive material of EVA and a PET film. After the sealing, the second measurement was performed with solar simulator AM1.5(100 mW/cm²).

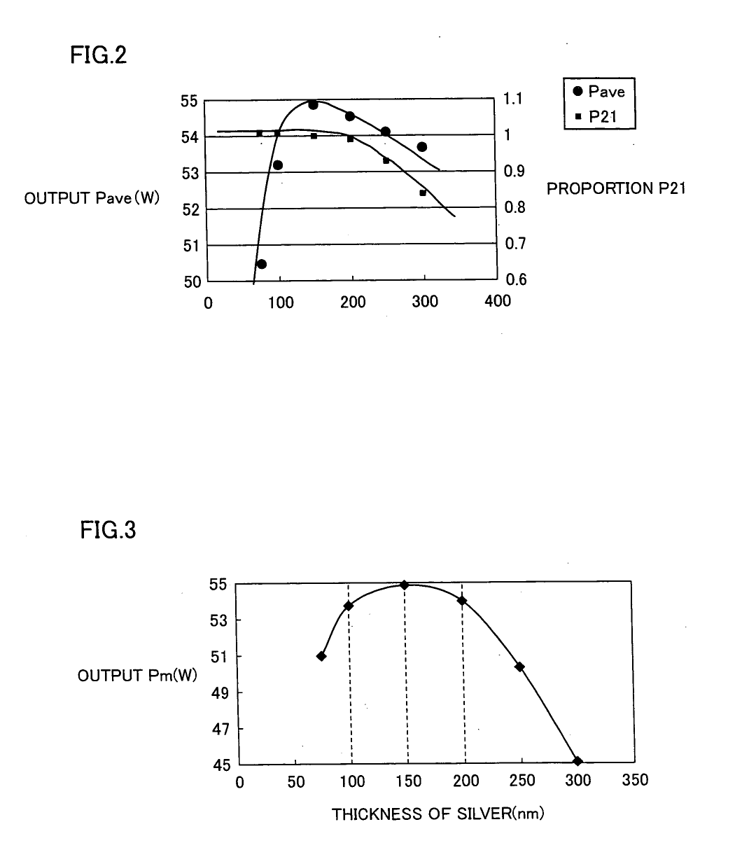

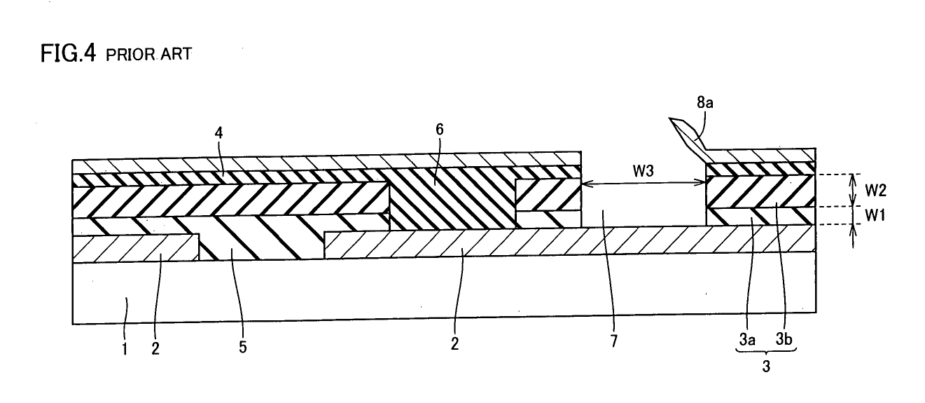

FIG. 2 shows average output Pave (W) and proportion P₂₁=(second average output/first average output) of a solar battery thus produced. FIG. 3 shows average output Pm (W) after formed in a module (i.e., Pm=Pave×P21).

### EXAMPLE 2

Processes were performed similarly to Example 1 except that the thickness of silver (back surface metal electrode) was set to be 100 nm. Similarly to Example 1, the back surface electrode separation line was observed by a microscope, and almost no burr was found. FIG. 2 shows average output Pave (W) and proportion P₂₁=(second average output/first average output) of a solar battery thus produced. FIG. 3 shows average output Pm (W) after formed in a module (i.e., Pm=Pave×P21).

### EXAMPLE 3

Processes were performed similarly to Example 1 except that the thickness of silver (back surface metal electrode) was set to be 200 nm. Similarly to Example 1, the back surface electrode separation line was observed by a microscope, and almost no burr was found. FIG. 2 shows average output Pave (W) and proportion P₂₁=(second average output/first average output) of a solar battery thus produced. FIG. 3 shows average output Pm (W) after formed in a module (i.e., Pm=Pave×P21).

### COMPARATIVE EXAMPLE 1

Processes were performed similarly to Example 1 except that the thickness of silver (back surface metal electrode) was set to be 75 nm. Similarly to Example 1, the back surface electrode separation line was observed by a microscope, and almost no burr was found. FIG. 2 shows average output Pave (W) and proportion P₂₁=(second average output/first average output) of a solar battery thus produced. FIG. 3 shows average output Pm (W) after formed in a module (i.e., Pm=Pave×P21).

### COMPARATIVE EXAMPLE 2

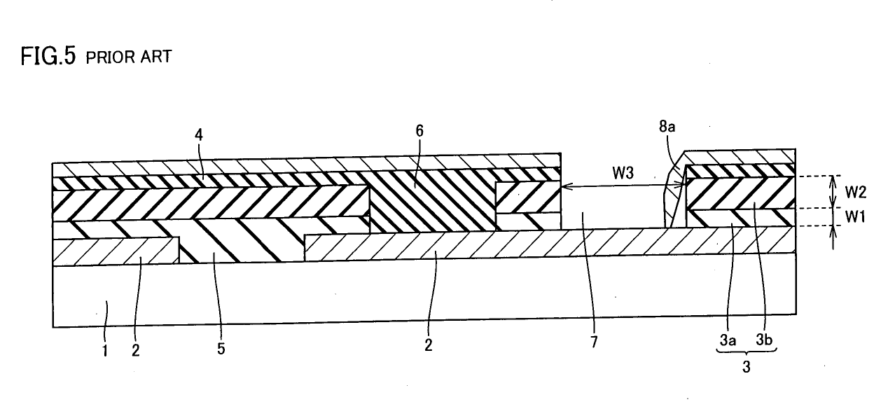

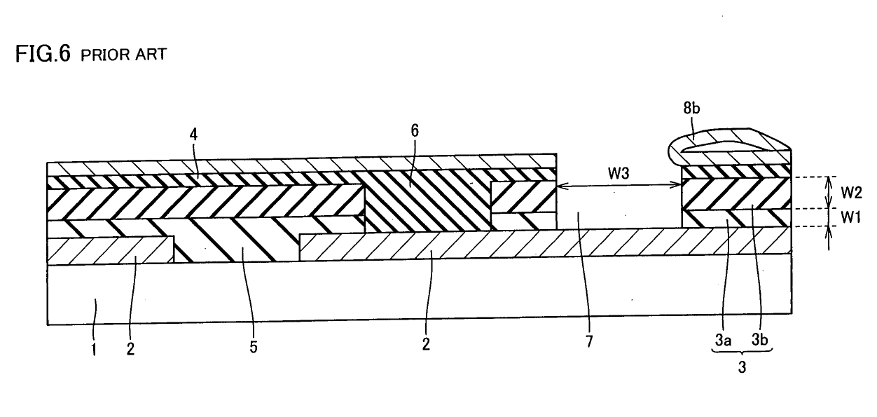

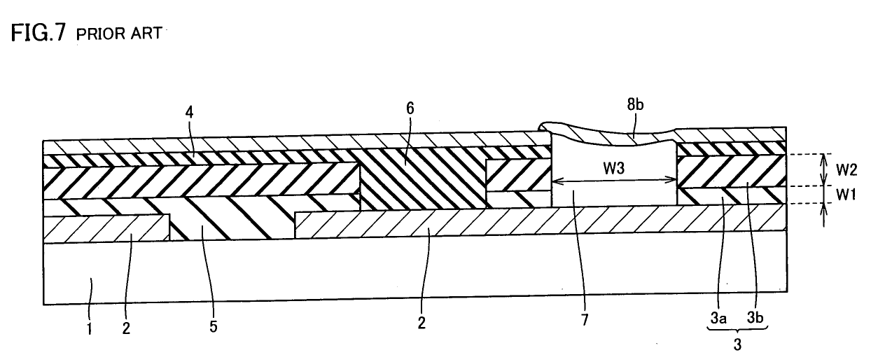

Processes were performed similarly to Example 1 except that the thickness of silver (back surface metal electrode) was set to be 250 nm. Similarly to Example 1, the back surface electrode separation line was observed by a microscope, and burrs 8b as shown in FIG. 5 were found in some portions. FIG. 2 shows average output Pave (W) and proportion P₂₁=(second average output/first average output) of a solar battery thus produced. FIG. 3 shows average output Pm (W) after formed in a module (i.e., Pm=Pave×P21).

### COMPARATIVE EXAMPLE 3

Processes were performed similarly to Example 1 except that the thickness of silver (back surface metal electrode) was set to be 300 nm. Similarly to Example 1, the back surface electrode separation line was observed by a microscope, and burrs 8b as shown in FIG. 5 were found in many portions. FIG. 2 shows average output Pave (W) and proportion P₂₁=(second average output/first average output) of a solar battery thus produced. FIG. 3 shows average output Pm (W) after formed in a module (i.e., Pm=Pave×P21).

From FIGS. 2 and 3, using the structure of the present invention, a solar battery can be produced without deterioration of properties around the back surface electrode, with good yield and high output of solar battery. It is considered that the properties are deteriorated when silver is thin, being affected by the resistance component of the electrode, which results in an increase in the series resistance and insufficient reflection rate. Conversely, when silver is thick, due to decreased workability of the back surface electrode layer, burrs are likely to be generated. Even before sealing, deterioration of properties occur due to leak, and the deterioration becomes significant after the sealing.

### EXAMPLE 4

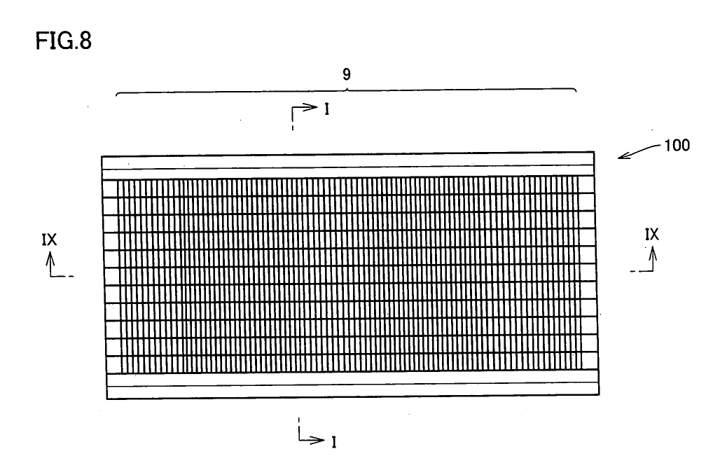

A see-through type solar battery having a cross sectional structure as shown in FIG. 9 along IX-IX of see-through type solar battery 100 of FIG. 8 was produced. The cross section along I-I is the same as shown in FIG. 1.

Using a glass substrate having a thickness of about 4.0 mm as insulation translucent substrate 11, SnO₂ (tin oxide) was deposited by thermal CVD method as transparent conductive film 12 on the glass substrate (substrate size 560 mm×925 mm).

Next, using fundamental harmonic of YAG laser, patterning of transparent conductive film 12 was performed. By setting the light to enter from the glass surface, transparent conductive film 12 was separated into rectangular pieces and surface electrode separation line 15 was formed. Thereafter, the substrate was subjected to an ultrasonic cleaning by pure water, and thereafter upper cell 13a was formed. Upper cell 13a was formed of a-Si:Hp layer, a-Si:Hi layer, and a-Si:Hn layer, and the total thickness W1 was about 0.25 μm.

Next, lower cell 13b was formed. Lower cell 13b was formed of μc-Si:Hp layer, μc-Si:Hi layer, and μc-Si:Hn layer, and the total thickness W2 was about 2.4 μm.

Next, using the second-harmonic generation of YAG laser, patterning using a laser was performed to lower cell 13b. By setting the light to enter from the glass surface, lower cell 13b was separated into rectangular pieces, and contact line 16 for electrically connecting transparent conductive film 12 and back surface electrode 14 was formed.

Next, by the magnetron sputtering method, ZnO (zinc oxide)/Ag of back surface electrode 14 was formed. Here, ZnO was set to have a thickness of 50 μm. The thickness of silver was set to be 150 nm.

Next, using a laser, patterning was performed to back surface electrode 14. By setting the light to enter from the glass surface, back surface electrode 14 was separated into rectangular pieces, and back surface electrode separation line 17 was formed. Here, in order to avoid damage to transparent conductive film 12 by the laser, the second-harmonic generation of Nd:YAG laser that is superior in passing transparent conductive film 12 was used as the laser. Width W1 of back surface electrode separation line 17 was set to be 85 μm.

Thereafter, a terminal was connected to the electrode portion, and not performing a cleaning step, a measurement was performed with solar simulator AM1.5 (100 mW/cm²). The measurement result was Isc: 1.124 A, Voc: 68.11V, F.F: 0.720, Pmax55.12 W.

Thereafter, protecting by a mask so that the electrode portion is not processed, opening portion 9 was formed by laser irradiation of second-harmonic generation of Nd:YAG from a glass surface. Here, it is preferable to select the laser processing conditions so as not to damage transparent conductive film 12, as in the case of surface electrode separation line 17 of back surface electrode 14. Here, width W4 of opening portion 9 was set to be 120 μm, pitch W5 of the opening portion was set to be 1.27 mm. Having been processed as described above, total area of opening portion 9 relative to an effective power generation area was set to be 10%. Without performing a cleaning step, a measurement was performed with solar simulator AM1.5 (100 mW/cm²). The measurement result was Isc: 1.011 A, Voc: 68.06V, F.F: 0.717, Pmax49.33 W.

Specifically, deterioration of properties due to see-through processing was about 10.5%, which was as great as the area of the opening portion of 10%, and therefore deterioration of the properties was not significant.

Further, sealing was performed on back surface electrode 14 side with glass thereafter. No deterioration of the properties was found.

### COMPARATIVE EXAMPLE 4

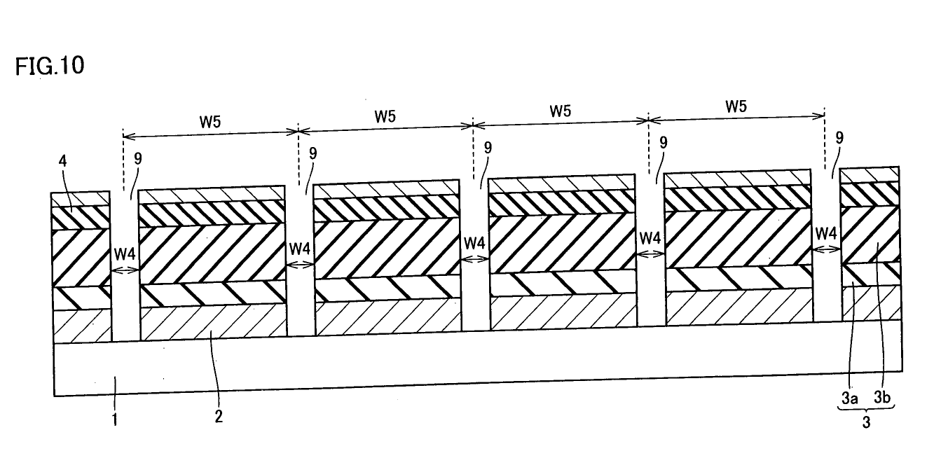

A see-through type solar battery having a cross sectional structure as shown in FIG. 10 along IX-IX of see-through type solar battery 100 of FIG. 8 was produced. The cross section along I-I is the same as shown in FIG. 1.

Except for the producing method of see-thorough opening portion 9, production was performed similarly to Example 4. As to see-through opening portion 9, using fundamental harmonic of YAG laser, width W4 of opening portion 9 was set to be 120 μm, pitch W5 of opening portion 9 was 1.27 mm, and then processing was performed.

Before performing see-through processing and without performing a cleaning step, the measurement result obtained with solar simulator AM1.5 (100 mW/cm²) was Isc: 1.122 A, Voc: 68.30V, F.F: 0.716, Pmax54.86 W.

After performing see-through processing and without performing a cleaning step, the measurement result obtained with solar simulator AM1.5 (100 mW/cm²) was Isc: 1.011 A, Voc: 54.61V, F.F: 0.540, Pmax29.81 W.

Specifically, deterioration of properties due to the see-through processing was about 45.6%, which was significant as compared to the area of the opening portion of 10%.

As apparent from Example 4 and Comparative Example 4, by a method in which processing is performed from a transparent conductive film and an opening portion is formed, significant deterioration of properties was found if a cleaning step was not performed.

Although the present invention has been described and illustrated in detail, it is clearly understood that the same is by way of illustration and example only and is not to be taken by way of limitation, the spirit and scope of the present invention being limited only by the terms of the appended claims.

1. A solar battery comprising a plurality of power generation regions having at least an insulation translucent substrate, a front surface electrode, a photoelectric conversion layer made of semiconductor films being stacked, and a back surface electrode, said front surface electrode and said back surface electrode of adjacent power generation regions being electrically connected, whereby the power generation regions are serially connected, wherein
said back surface electrode has a back surface metal electrode having a thickness of 100 nm-200 nm.

2. The solar battery according to claim 1, wherein
in order from the insulation translucent substrate side, said photoelectric conversion layer is formed by stacking an upper photoelectric conversion layer in which each of p-type, i-type and n-type semiconductor films formed of amorphous silicon is stacked, and a lower photoelectric conversion layer in which each of p-type, i-type and n-type semiconductor films formed of microcrystalline silicon is stacked.

3. The solar battery according to claim 2, wherein
a plurality of opening portions processed in a manner of slits perpendicular to an integration direction to transmit light to their back surface side are formed, and
said photoelectric conversion layer and said back surface electrode are separated at said opening portion.

4. The solar battery according to claim 3, wherein
a transparent conductive film is unseparated at said opening portion.

5. The solar battery according to claim 1, wherein
a plurality of opening portions processed in a manner of slits perpendicular to an integration direction to transmit light to their back surface side are formed, and
said photoelectric conversion layer and said back surface electrode are separated at said opening portion.

6. The solar battery according to claim 5, wherein
a transparent conductive film is unseparated at said opening portion.

7. A see-through type solar battery module, comprising a plurality of power generation regions having at least an insulation translucent substrate, a front surface electrode, a photoelectric conversion layer made of semiconductor films being stacked, and a back surface electrode, said front surface electrode and said back surface electrode of adjacent power generation regions being electrically connected, whereby the power generation regions are serially connected, wherein
said back surface electrode has a back surface metal electrode having a thickness of 100 nm-200 nm,
a plurality of opening portions processed in a manner of slits perpendicular to an integration direction to transmit light to their back surface side are formed, and
a back surface electrode side is sealed with an adhesive layer and a transparent sealing material.

8. A method for manufacturing a solar battery including a plurality of power generation regions having at least an insulation translucent substrate, a front surface electrode, a photoelectric conversion layer made of semiconductor films being stacked, and a back surface electrode, said front surface electrode and said back surface electrode of adjacent power generation regions being electrically connected, whereby the plurality of the power generation regions are serially connected, comprising at least the steps of:
forming a back surface electrode having a back surface metal electrode having a thickness of 100 nm-200 nm; and
separating said back surface metal electrode by laser processing, wherein
a cleaning step is not performed after separating said back surface metal electrode.

9. The method according to claim 8, wherein
said laser processing of said back surface metal electrode is performed by irradiation of second-harmonic generation of Nd:YAG or Nd:YVO₄ laser from a glass surface.
